(19) United States
(12) Patent Application Publication
(10) Pub. No.: US 2014/0037109 A1
(43) Pub. Date: Feb. 6, 2014

(54) METHOD AND APPARATUS FOR ALARM SERVICE USING CONTEXT AWARENESS IN PORTABLE TERMINAL

(71) Applicant: Samsung Electronics Co. Ltd., Suwon-si (KR)

(72) Inventor: Ji-Hye BAN, Suwon-si (KR)

(73) Assignee: Samsung Electronics Co. Ltd., Suwon-si (KR)

(21) Appl. No.: 13/957,896

(22) Filed: Aug. 2, 2013

(30) Foreign Application Priority Data
Aug. 3, 2012 (KR) 10-2012-0085327

(51) Int. Cl. H03G 3/20

(52) U.S. Cl. CPC H03G 3/20
USPC 381/107

(57) ABSTRACT

A method and apparatus for an alarm service using context awareness in a portable terminal are provided. A control method for preventing the disruption of sleep includes sensing if a user is in a sleep state and, when the user is in the sleep state, adjusting a volume level to a preset volume level, and adjusting screen brightness to a preset screen brightness when the user is in the sleep state.

### PRIORITY

This application claims the benefit under 35 U.S.C. §119(a) of a Korean patent application filed on Aug. 3, 2012 in the Korean Intellectual Property Office and assigned Serial No. 10-2012-0085327, the entire disclosure of which is hereby incorporated by reference.

### BACKGROUND OF THE INVENTION

1. Field of the Invention:

The present invention relates to a portable terminal. More particularly, the present invention relates to a method and apparatus for an alarm service in the portable terminal.

2. Description of the Related Art:

Portable terminals provide various services for user convenience such as functions of text message transmission/reception, various information search using the Internet, reception of contents of a photo, a movie, etc., from the Internet and the like, besides voice telephony. Also, besides the aforementioned functions, the portable terminals are additionally providing a variety of supplementary functions such as a schedule management function and an alarm function.

Commonly, a user makes much use of the alarm function by using a portable terminal rather than a separate alarm clock. The portable terminal performs the voice telephony and text data transmission/reception functions besides the alarm function. So, when the user receives a call while the user is sleeping, his/her sleep may be disturbed due to a reception notification function unless he/she turns off the portable terminal or uninstalls a battery from the portable terminal. And, to avoid the sleep disturbance by a bell sound or vibration for reception notification, sometimes, the user turns off the portable terminal or uninstalls the battery from the portable terminal.

However, if the user turns off the portable terminal in order to avoid the sleep disturbance, there is a problem of potentially failing to receive an urgent important call. Also, because the portable terminal does not store a history of incoming calls in a power off state, the user cannot know if he/she has received calls even after the portable terminal turns on. And, because the portable terminal turns off, the user cannot use the set alarm function of the portable terminal.

Meanwhile, in some cases, a user wakes up during sleep to check the time by using a portable terminal. At this time, the user can press a hardware key and turn on a Liquid Crystal Display (LCD) screen to check the time. Then, the user's sleep by be disturbed from a bight illumination of the screen.

Accordingly, there is a need for a method and apparatus for, when performing an alarm function, preventing sleep from being disturbed in a portable terminal.

The above information is presented as background information only to assist with an understanding of the present disclosure. No determination has been made, and no assertion is made, as to whether any of the above might be applicable as prior art with regard to the present invention.

### SUMMARY OF THE INVENTION

Aspects of the present invention are to address at least the above-mentioned problems and/or disadvantages and to provide at least the advantages below. Accordingly, an aspect the present invention is to provide a method and apparatus for an alarm service using context awareness in a portable terminal.

According to one aspect of the present invention, a control method for preventing the disruption of sleep is provided. The method includes sensing if a user is in a sleep state and, when the user is in the sleep state, adjusting a volume level to a preset volume level.

In the method of an exemplary embodiment of the present invention, adjusting the volume level to the preset volume level when the user is in the sleep state includes determining a currently set volume level and, when the currently set volume level is greater than the preset volume level, setting the currently set volume level to the preset volume level.

The method further includes restoring the preset volume level to the original volume level when the sleep state is ended.

The method further includes adjusting screen brightness to a preset screen brightness when the user is in the sleep state.

In the method, adjusting the screen brightness to the preset screen brightness when the user is in the sleep state includes determining if it is dark and, when it is dark, setting the screen brightness to the preset screen brightness and, when it is not dark, maintaining current screen brightness.

The method further includes restoring the preset screen brightness to the original screen brightness when the sleep state is ended.

In accordance with another aspect of the present invention, an alarm service method using context awareness is provided. The method includes sensing if a user is in a sleep state and, when the user is in the sleep state, sensing at least one or more of a terminal motion, user approach or not, and a terminal motion pattern and, when one of the terminal motion, the user approach or not, and the terminal motion pattern is sensed, displaying at least one or more of a current time and a time remaining until an alarm time.

The method further includes outputting at least one or more of the current time and the time remaining until the alarm time by voice when one of the terminal motion, a voice recognition instruction, user approach or not, and the terminal motion pattern is sensed.

In the method, displaying at least one or more of the current time and the time remaining until the alarm time includes activating an application processor, acquiring a current time and a time remaining until an alarm time from the application processor, and displaying at least one or more of the current time and the time remaining until the alarm time.

In the method, displaying at least one or more of the current time and the time remaining until the alarm time includes activating an application processor, determining, by the application processor, the current time and the time remaining until the alarm time, and displaying, by the application processor, at least one or more of the current time and the time remaining until the alarm time.

In accordance with an aspect of the present invention, an alarm service method using context awareness is provided. The method includes sensing if a user is in a sleep state and, when the user is in the sleep state, sensing at least one or more of whether a terminal motion is maintained and whether a user input is maintained and, when one of whether the terminal motion is maintained and whether the user input is maintained is sensed, displaying a pop-up window inquiring alarm release.

The method further includes releasing a preset alarm when the user selects the alarm release through the pop-up window inquiring the alarm release.

In accordance with another aspect of the present invention, a sleep recognition method is provided. The method includes sensing at least one or more of a terminal motion, illumination, and whether a portable terminal is laid down with a screen facing downward through a sensor, and determining that the user is in the sleep state, when the terminal motion is sensed during a predetermined time and the illumination is equal to or is less than a threshold value and the portable terminal is not laid down with the screen downward.

The method further includes determining that the user is not in the sleep state when at least one of the terminal motion, the illumination, and whether the portable terminal has been laid down with the screen facing downward does not meet a corresponding condition.

In accordance with another aspect of the present invention, a sleep recognition method is provided. The method includes determining a location of a portable terminal and, when a location of the portable terminal is a preset location, sensing at least one or more of a terminal motion, illumination, and whether a portable terminal is laid down with a screen facing downward through a sensor, and determining that the user is in the sleep state, when the terminal motion is sensed during a predetermined time and the illumination is equal to or is less than a threshold value and the portable terminal is not laid down with the screen downward.

The method further includes determining that the user is not in the sleep state when at least one of the terminal motion, the illumination, and whether the portable terminal has been laid down with the screen facing downward does not meet a corresponding condition.

In accordance with another aspect of the present invention, an electronic device is provided. The electronic device includes one or more processors, a memory, and one or more programs stored in the memory and configured to be executable by the one or more processors. The program includes an instruction of sensing if a user is in a sleep state and, when the user is in the sleep state, adjusting a volume level to a preset volume level.

In the electronic device, the instruction of adjusting the volume level to the preset volume level when the user is in the sleep state determines a currently set volume level and, when the currently set volume level is greater than the preset volume level, sets the currently set volume level to the preset volume level.

The program further includes an instruction of restoring the preset volume level to the original volume level when the sleep state is ended.

The program further includes an instruction of adjusting screen brightness to a preset screen brightness when the user is in the sleep state.

In the electronic device, the instruction of adjusting the screen brightness to the preset screen brightness when the user is in the sleep state determines if it is dark and, when it is dark, sets the screen brightness to the preset screen brightness and, when it is not dark, maintains current screen brightness.

The program further includes an instruction of restoring the preset screen brightness to the original screen brightness when the sleep state is ended.

In accordance with another aspect of the present invention, an electronic device is provided. The electronic device includes one or more processors, a memory, and one or more programs stored in the memory and configured to be executable by the one or more processors. The program includes an instruction of sensing if a user is in a sleep state and, when the user is in the sleep state, sensing at least one or more of an electronic device motion, user approach or not, and an electronic device motion pattern and, when one of the electronic device motion, the user approach or not, and the electronic device motion pattern is sensed, displaying at least one or more of a current time and a time remaining until an alarm time.

The program further includes an instruction of outputting at least one or more of the current time and the time remaining until the alarm time by voice when one of the electronic device motion, a voice recognition instruction, user approach or not, and the electronic device motion pattern is sensed.

In the electronic device, the instruction of displaying at least one or more of the current time and the time remaining until the alarm activates an application processor, acquires a current time and a time remaining until an alarm time from the application processor, and displays at least one or more of the current time and the time remaining until the alarm time.

In the electronic device, the instruction of displaying at least one or more of the current time and the time remaining until the alarm activates an application processor, determines, by the application processor, the current time and the time remaining until the alarm time, and displays, by the application processor, at least one or more of the current time and the time remaining until the alarm time.

In accordance with another aspect of the present invention, an electronic device is provided. The electronic device includes one or more processors, a memory, and one or more programs stored in the memory and configured to be executable by the one or more processors. The program includes an instruction of sensing if a user is in a sleep state and, when the user is in the sleep state, sensing at least one or more of whether an electronic device motion is maintained and whether a user input is maintained and, when one of whether the electronic device motion is maintained and whether the user input is maintained is sensed, displaying a pop-up window inquiring alarm release.

The program further includes an instruction of releasing a preset alarm when the user selects the alarm release through the pop-up window inquiring the alarm release.

In accordance with another aspect of the present invention, an electronic device is provided. The electronic device includes one or more processors, a memory, and one or more programs stored in the memory and configured to be executable by the one or more processors. The program includes an instruction of sensing at least one or more of an electronic device motion, illumination, and whether an electronic device is laid down with a screen facing downward through a sensor, and determining that the user is in the sleep state, when the electronic device motion is sensed during a predetermined time and the illumination is equal to or is less than a threshold value and the electronic device is not laid down with the screen downward.

The program further includes an instruction of determining that the user is not in the sleep state when at least one of the electronic device motion, the illumination, and whether the electronic device has been laid down with the screen facing downward does not meet a corresponding condition.

In accordance with another aspect of the present invention, an electronic device is provided. The electronic device includes one or more processors, a memory, and one or more programs stored in the memory and configured to be executable by the one or more processors. The program includes an instruction of determining a location of an electronic device and, when a location of the electronic device is a preset location, sensing at least one or more of an electronic device motion, illumination, and whether an electronic device is laid down with a screen facing downward through a sensor, and determining that the user is in the sleep state, when the electronic device motion is sensed during a predetermined time and the illumination is equal to or is less than a threshold value and the electronic device is not laid down with the screen downward.

The program further includes an instruction of determining that the user is not in the sleep state when at least one of the electronic device motion, the illumination, and whether the electronic device has been laid down with the screen facing downward does not meet a corresponding condition.

In accordance with another aspect of the present invention, an operation method of an electronic device is provided. The method includes, in a state where a predetermined function has been set, sensing a first state through a sensing module by control of a first processor, activating, by the first processor, a second processor that is in a deactivation state, and outputting predetermined function related information by control of the activated second processor.

In accordance with another aspect of the present invention, an electronic device is provided. The electronic device includes one or more processors configured to execute one or more computer executable instructions, and a memory configured to store data and the one or more computer executable instructions. The one or more computer executable instructions comprise one or more computer executable instructions for, in a state where a predetermined function has been set, sensing a first state through a sensing module by control of a first processor, activating, by the first processor, a second processor that is in a deactivation state, and outputting predetermined function related information by control of the activated second processor.

In accordance with another aspect of the present invention, an operation method of an electronic device is provided. The electronic device includes sensing if the electronic device is in a user sleep environment and, when the electronic device is in the user sleep environment, at least one of, if a set volume level is greater than a reference volume level, adjusting the set volume level to the reference volume level and, if a set screen brightness is greater than a reference screen brightness, adjusting the set screen brightness to the reference screen brightness.

In accordance with another aspect of the present invention, an electronic device is provided. The electronic device includes one or more processors configured to execute one or more computer executable instructions, and a memory configured to store data and the one or more computer executable instructions. The one or more computer executable instructions comprise one or more computer executable instructions for sensing if the electronic device is in the a user sleep environment and, when the electronic device is in the user sleep environment, at least one of, if a set volume level is greater than a reference volume level, adjusting the set volume level to the reference volume level and, and if a set screen brightness is greater than a reference screen brightness, adjusting the set screen brightness to the reference screen brightness.

In accordance with another aspect of the present invention, an operation method of an electronic device is provided. The electronic device includes sensing if the electronic device is in a user sleep environment and, when the electronic device is in the user sleep environment, sensing at least one of a motion of the electronic device and a preset input, and displaying an alarm release pop-up window.

In accordance with another aspect of the present invention, an electronic device is provided. The electronic device includes one or more processors configured to execute one or more computer executable instructions, and a memory configured to store data and the one or more computer executable instructions. The one or more computer executable instructions comprise one or more computer executable instructions for sensing if the electronic device is in a user sleep environment and, when the electronic device is in the user sleep environment, sensing at least one of a motion of the electronic device and a preset input, and displaying an alarm release pop-up window.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will become more apparent from the following description taken in conjunction with the accompanying drawings, in which:

FIG. 1A is a flowchart illustrating a method for recognizing a user sleep state in a portable terminal according to a first exemplary embodiment of the present invention;

FIG. 1B is a flowchart illustrating a method for recognizing a user sleep state in a portable terminal according to a second exemplary embodiment of the present invention;

FIG. 2A is a flowchart illustrating a method for recognizing a user sleep state in a portable terminal according to a third exemplary embodiment of the present invention;

FIG. 2B is a flowchart illustrating a method for recognizing a user sleep state in a portable terminal according to a fourth exemplary embodiment of the present invention;

FIG. 2C is a block diagram illustrating an apparatus for recognizing a user sleep state in accordance with the method of FIG. 2A, in a portable terminal according to the third exemplary embodiment of the present invention;

FIG. 3A is a flowchart illustrating a method for providing a sound sleep service after sleep state recognition in a portable terminal according to a fifth exemplary embodiment of the present invention;

FIG. 3B is a block diagram illustrating an apparatus for providing a sound sleep service in accordance with the method of FIG. 3A, in a portable terminal according to the fifth exemplary embodiment of the present invention;

FIG. 4A is a flowchart illustrating a method for providing a sound sleep service after sleep state recognition in a portable terminal according to a sixth exemplary embodiment of the present invention;

FIG. 4B is a block diagram illustrating an apparatus for providing a sound sleep service in accordance with the method of FIG. 4A, in a portable terminal according to the sixth exemplary embodiment of the present invention;

FIG. 5A is a flowchart illustrating a method for providing a sound sleep service after sleep state recognition in a portable terminal according to a seventh exemplary embodiment of the present invention;

FIG. 5B is a block diagram illustrating an apparatus for providing a sound sleep service in accordance with the method of FIG. 5A, in a portable terminal according to the seventh exemplary embodiment of the present invention;

FIG. 6 is a block diagram illustrating a construction of an electronic device according to an exemplary embodiment of the present invention;

FIG. 7 is a diagram illustrating an alarm release pop-up window according to an exemplary embodiment of the present invention; and

FIGS. 8A and 8B are diagrams illustrating an example of alarm release setting according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Below, the present disclosure describes a method and apparatus for an alarm service using context awareness in a portable terminal.

Particularly, in the present disclosure, an Application Processor (AP) provides a sensor-based intelligent service in a user sleep state by allowing a sensing-only processor that is separate from the application processor to control sensor driving and sensor based information processing, based on a Seamless Sensor Platform (SSP) that is a low-power sensing platform for always-on sensing.

That is, the present disclosure provides a sound sleep mode service of allowing the application processor of the portable terminal to seamlessly sense acceleration, illumination and the like at low power even in a user sleep state based on the SSP, and automatically detect the user sleep state by using the SSP, and automatically mute an audio sound of the portable terminal such as a bell sound/media sound and the like in order to not disturb a user's sleep, or automatically adjust the brightness of a screen in order to prevent user's dazzling. Also, the present disclosure displays or outputs a current time and a time remaining until an alarm time by voice if the user touches or approaches the portable terminal before an alarm time set by the user or inputs a preset voice command, thereby being capable of allowing the user to experience a new alarm service and a service of recognizing a case where the user already wakes up or comes into other action before the alarm goes off and releasing the alarm.

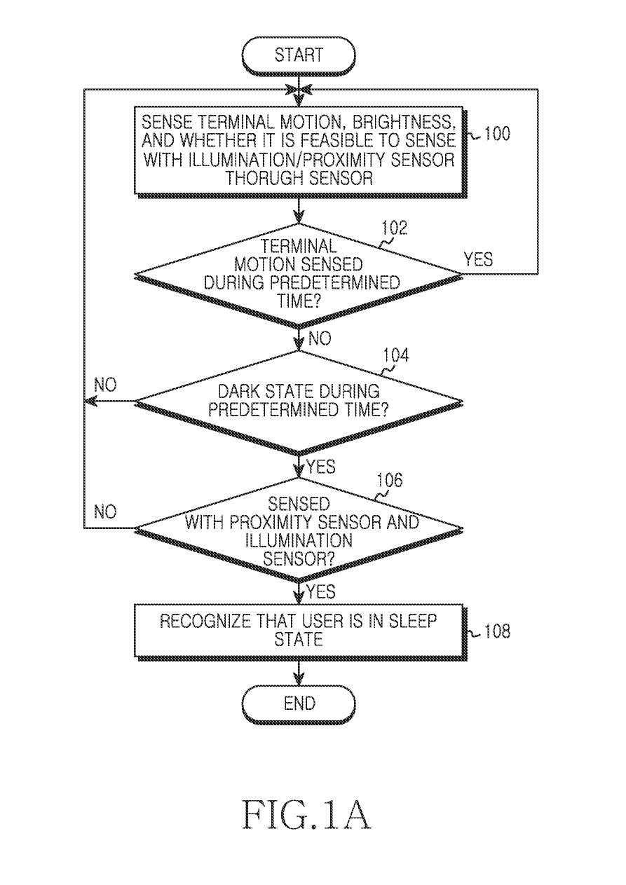

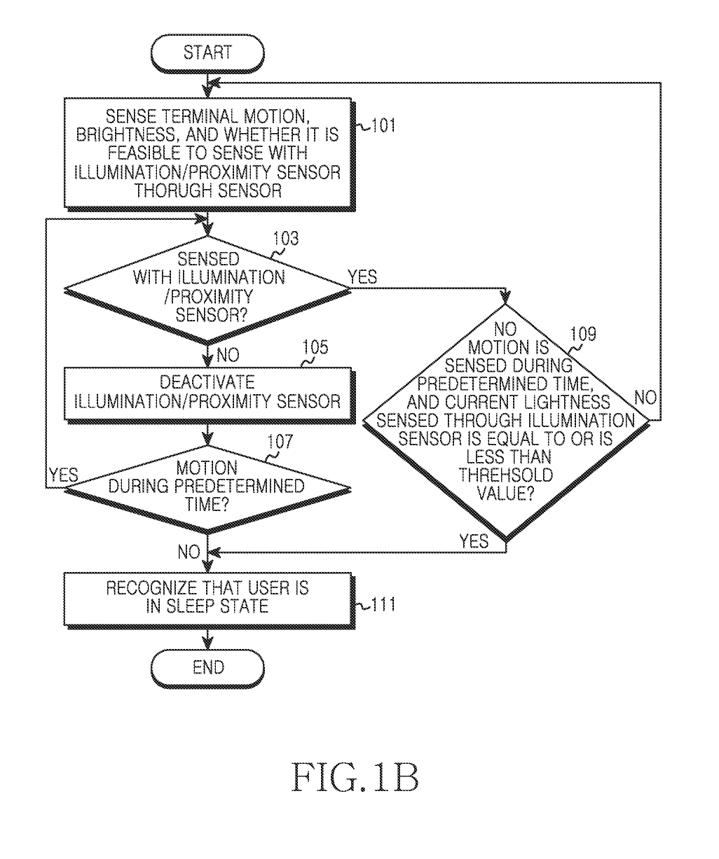

FIG. 1A is a flowchart illustrating a method for recognizing a user sleep state in a portable terminal according to a first exemplary embodiment of the present invention.

Referring to FIG. 1A, in operation 100, a sensor processor of the portable terminal detects, through a sensor module (e.g., an acceleration sensor, an illumination sensor, and a proximity sensor), a terminal motion, the brightness of light, and whether it is feasible to sense with the proximity sensor and illumination sensor of the portable terminal For example, the sensor processor senses a motion through the acceleration sensor, senses the amount of surrounding light through the illumination sensor, and senses if an object approaches through the proximity sensor. Also, the portable terminal can detect whether it is feasible to sense with the proximity sensor and illumination sensor of the portable terminal, through the sensing results of the proximity sensor and illumination sensor. Here, a state incapable of sensing with the proximity sensor and illumination sensor of the portable terminal is a state where the portable terminal has been laid down with a Liquid Crystal Display (LCD) screen downward, and represents a state where the portable terminal cannot sense because the portable terminal has been laid down in a direction in which the proximity sensor and illumination sensor are installed or because the proximity sensor and illumination sensor are in close contact with any object, or a state where the proximity sensor and illumination sensor have not been installed.

According to the realization, the portable terminal determines that it is in a state incapable of sensing with the proximity sensor and illumination sensor of the portable terminal, with only the sensing result of the proximity sensor, i.e., if an object continuously approaches the portable terminal during a predetermined time. According to another realization, the portable terminal can sense if the portable terminal has been laid down with the LCD screen downward, based on the sensing results of a gyroscope sensor and an acceleration sensor. That is, when the proximity sensor and the illumination sensor are installed in a location where the LCD screen is installed, if the portable terminal is laid down with the LCD screen downward, the portable terminal determines that it is in a state incapable of sensing with the proximity sensor and the illumination sensor. In the present exemplary embodiment, a basis for determining whether it is feasible to sense with the proximity sensor and illumination sensor of the portable terminal is not limited to the use of the gyroscope sensor, the acceleration sensor, and the proximity sensor, and can be realized variously by a combination of at least any one or more of the gyroscope sensor, the acceleration sensor, the proximity sensor, and any other suitable sensor.

After that, if it is determined in operation 102 that a terminal motion is sensed during a predetermined time, the sensor processor of the portable terminal returns to operation 100.

Meanwhile, if it is determined in operation 102 that the terminal motion is not sensed during the predetermined time, the sensor processor of the portable terminal proceeds to operation 104 and determines if a dark state is maintained during a predetermined time. That is, the sensor processor determines if light is measured during a predetermined time through the illumination sensor.

Next, if it is determined in operation 104 that the dark state is not maintained during the predetermined time, i.e., if it is not dark, the sensor processor of the portable terminal returns to operation 100. Meanwhile, if it is determined in operation 104 that the dark state is maintained during the predetermined time, the sensor processor of the portable terminal proceeds to operation 106 and determines if the portable terminal is in a state incapable of sensing with the proximity sensor and illumination sensor of the portable terminal. In the realization, the sensor processor can determine if it is night or day by using a current time provided from an application processor instead of using the sensing result of the illumination sensor.

After that, if it is determined in operation 106 that the portable terminal is in the state incapable of sensing with the proximity sensor and illumination sensor of the portable terminal, the sensor processor of the portable terminal returns to operation 100. Meanwhile, if it is determined in operation 106 that the portable terminal is in a state capable of sensing with the proximity sensor and illumination sensor of the portable terminal, the sensor processor proceeds to operation 108 and recognizes that a user of the portable terminal is in a sleep state.

Next, the sensor processor terminates the procedure of the present exemplary embodiment.

That is, the user sleep state sensing of FIG. 1A is to sense whether the portable terminal, an electronic device, is in a user sleep environment. The process of sensing whether the portable terminal is in a user sleep environment can include a process of sensing through a sensing sensor at least one or more of a motion of the electronic device, illumination around the electronic device, and whether the electronic device has been laid down with its touch screen facing the surface on which it is laid.

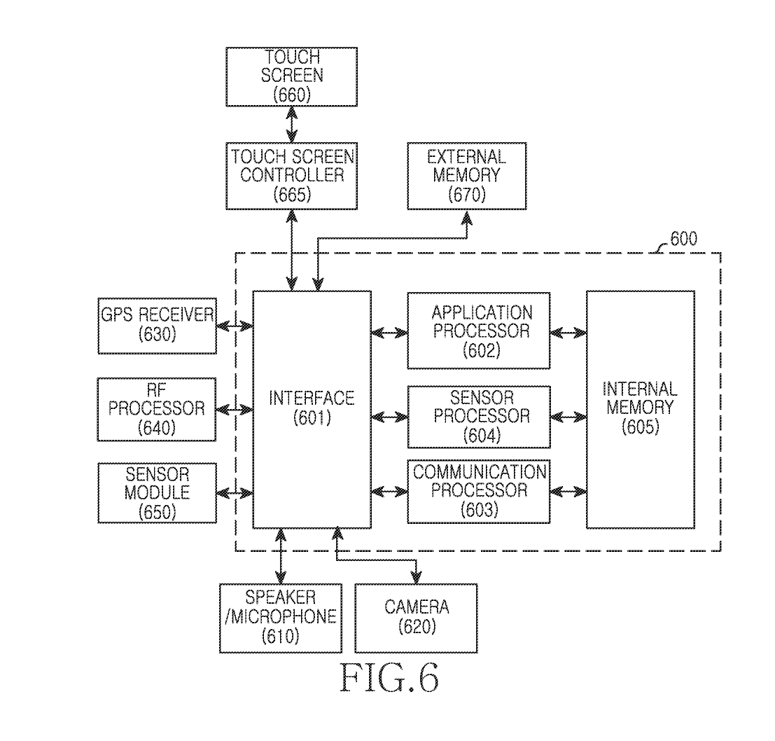

An instruction set for each operation of FIG. 1A can be stored as one or more modules in memories 605 and 670 of FIG. 6. In this case, the modules stored in the memories 605 and 670 can be executed by one or more processors.

FIG. 1B is a flowchart illustrating a method for recognizing a user sleep state in a portable terminal according to a second exemplary embodiment of the present invention.

Referring to FIG. 1B, in operation 101, a sensor processor of the portable terminal detects, through a sensor module (e.g., an acceleration sensor, an illumination sensor, and a proximity sensor), a terminal motion, the brightness of light, and whether it is feasible to sense with the proximity sensor and illumination sensor of the portable terminal. For example, the sensor processor senses a motion through the acceleration sensor, senses the amount of surrounding light through the illumination sensor, and senses if an object approaches through the proximity sensor. Also, the portable terminal can detect whether it is feasible to sense with the proximity sensor and illumination sensor of the portable terminal, through the sensing results of the proximity sensor and illumination sensor. Here, a state incapable of sensing with the proximity sensor and illumination sensor of the portable terminal is a state where the portable terminal has been laid down with an LCD screen faced downward, and represents a state where the portable terminal cannot sense because the portable terminal has been laid down in direction in which the proximity sensor and illumination sensor are installed or because the proximity sensor and illumination sensor are in close contact with any object, or a state where the proximity sensor and illumination sensor have not been installed.

According to the realization, the portable terminal determines that it is in a state incapable of sensing with the proximity sensor and illumination sensor of the portable terminal, with only the sensing result of the proximity sensor, i.e., if an object continuously approaches the portable terminal during a predetermined time. According to another realization, the portable terminal can sense if the portable terminal has been laid down with the LCD screen downward, based on the sensing results of a gyroscope sensor and an acceleration sensor. That is, when the proximity sensor and the illumination sensor are installed in a location where the LCD screen is installed, if the portable terminal is laid down with the LCD screen faced downward, the portable terminal determines that it is in a state incapable of sensing with the proximity sensor and the illumination sensor. In the present exemplary embodiment, a basis for determining whether it is feasible to sense with the proximity sensor and illumination sensor of the portable terminal is not limited to the use of the gyroscope sensor, the acceleration sensor, and the proximity sensor, and can be realized variously by a combination of at least any one or more of the gyroscope sensor, the acceleration sensor, the proximity sensor, and any other suitable sensor.

After that, in operation 103, the sensor processor of the portable terminal determines whether it is feasible to sense with the illumination sensor and the proximity sensor. If it is determined in operation 103 that the portable terminal is in a state incapable of sensing with the illumination sensor and the proximity sensor, the sensor processor of the portable terminal proceeds to operation 105 and deactivates the illumination/proximity sensor. Next, the sensor processor of the portable terminal proceeds to operation 107 and determines if a terminal motion is sensed during a predetermined time. Here, the reason of deactivating the illumination/proximity sensor is for reducing power consumption by deactivating unnecessary sensors. If it is determined in operation 107 that the terminal motion is sensed during the predetermined time, the sensor processor of the portable terminal returns to operation 103. Meanwhile, if it is determined in operation 107 that the terminal motion is not sensed during the predetermined time, the sensor processor of the portable terminal proceeds to operation 111.

Meanwhile, if it is determined in operation 103 that the portable terminal is in a state capable of sensing with the illumination sensor and the proximity sensor, the sensor processor of the portable terminal proceeds to operation 109 and determines if a terminal motion is not sensed during a predetermined time and current brightness sensed through the illumination sensor is equal to or is less than a threshold value. If it is determined in operation 109 that the terminal motion is not sensed during the predetermined time and the current brightness sensed through the illumination sensor is equal to or is less than the threshold value, the sensor processor of the portable terminal proceeds to operation 111 and, otherwise, returns to operation 101.

Next, in operation 111, the sensor processor of the portable terminal recognizes that a user of the portable terminal is in a sleep state.

After that, the sensor processor of the portable terminal terminates the procedure of the present exemplary embodiment.

An instruction set for each operation of FIG. 1B can be stored as one or more modules in memories 605 and 670 of FIG. 6. In this case, the modules stored in the memories 605 and 670 can be executed by one or more processors.

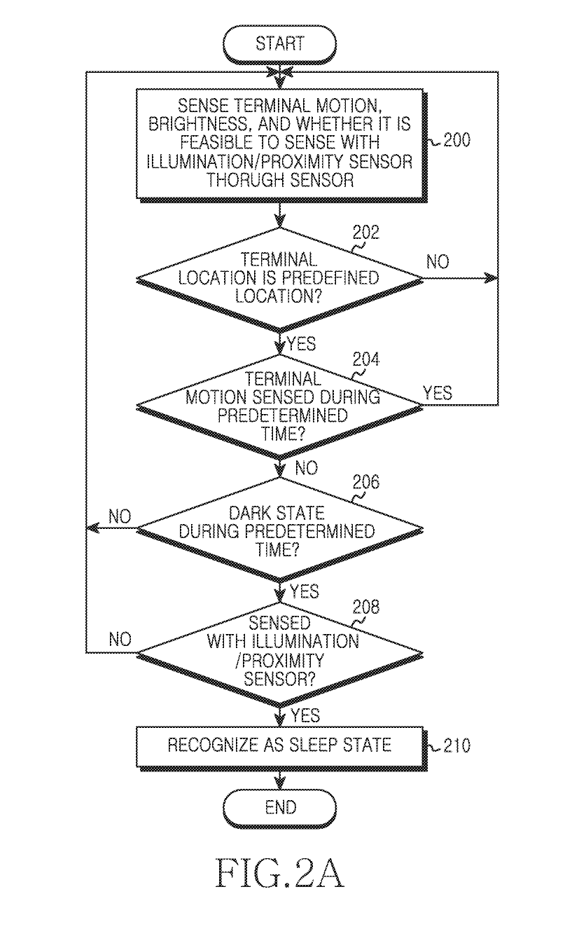

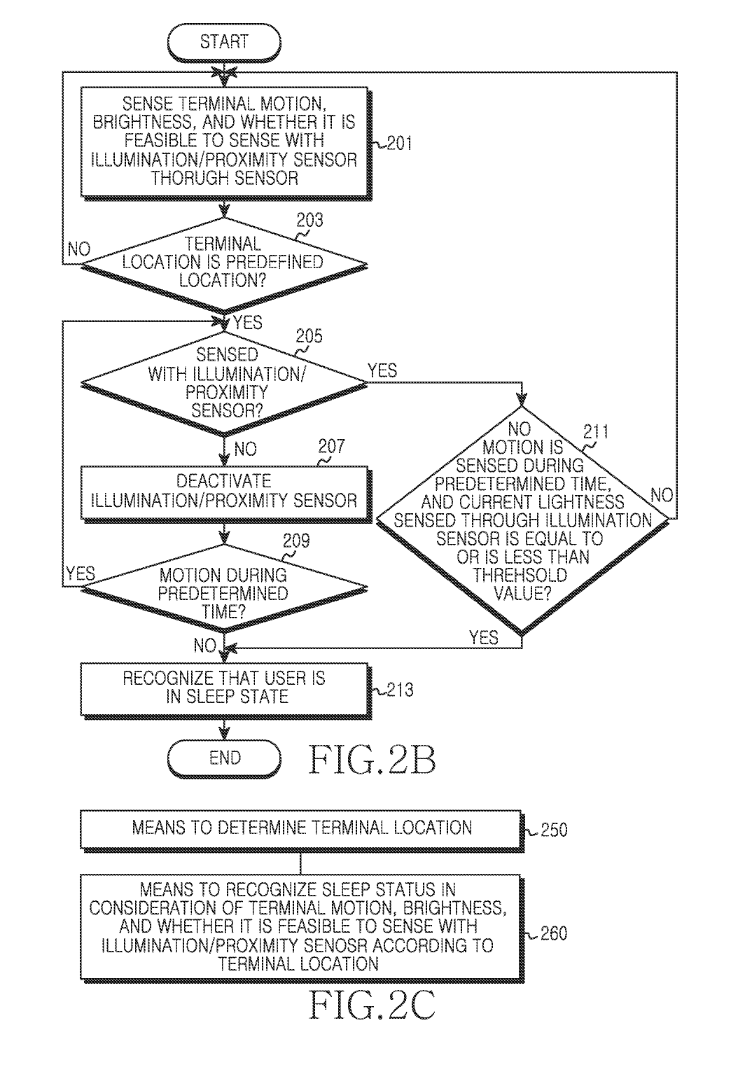

FIG. 2A is a flowchart illustrating a method for recognizing a user sleep state in a portable terminal according to a third exemplary embodiment of the present invention.

Referring to FIG. 2A, in operation 200, a sensor processor of the portable terminal detects, through a sensor module (e.g., an acceleration sensor, an illumination sensor, and a proximity sensor), a terminal motion, the brightness of light, and whether it is feasible to sense with the proximity sensor and illumination sensor of the portable terminal. For example, the sensor processor senses a motion through the acceleration sensor, senses the amount of surrounding light through the illumination sensor, and senses if an object approaches through the proximity sensor. Also, the portable terminal can detect whether it is feasible to sense with the proximity sensor and illumination sensor of the portable terminal, through the sensing results of the proximity sensor and illumination sensor. Here, a state incapable of sensing with the proximity sensor and illumination sensor of the portable terminal is a state where the portable terminal has been laid down with an LCD screen downward, and represents a state where the portable terminal cannot sense because the portable terminal has been laid down in direction in which the proximity sensor and illumination sensor are installed or because the proximity sensor and illumination sensor are in close contact with any object, or a state where the proximity sensor and illumination sensor have not been installed.

According to the realization, the portable terminal determines that it is in a state incapable of sensing with the proximity sensor and illumination sensor of the portable terminal, with only the sensing result of the proximity sensor, i.e., if an object continuously approaches the portable terminal during a predetermined time. According to another realization, the portable terminal can sense if the portable terminal has been laid down with the LCD screen downward, based on the sensing results of a gyroscope sensor and an acceleration sensor. That is, when the proximity sensor and the illumination sensor are installed in a location where the LCD screen is installed, if the portable terminal is laid down with the LCD screen faced downward, the portable terminal determines that it is in a state incapable of sensing with the proximity sensor and the illumination sensor. In the present exemplary embodiment, a basis for determining whether it is feasible to sense with the proximity sensor and illumination sensor of the portable terminal is not limited to the use of the gyroscope sensor, the acceleration sensor, and the proximity sensor, and can be realized variously by a combination of at least any one or more of the gyroscope sensor, the acceleration sensor, and the proximity sensor.

Next, in operation 202, the sensor processor of the portable terminal determines if a location of the portable terminal is consistent with a predefined location (e.g., a home) through a Global Positioning System (GPS) receiver. If it is determined in operation 202 that the location of the portable terminal is not consistent with the predefined location, the sensor processor of the portable terminal returns to operation 200.

According to the realization, in the absence of the GPS receiver, the sensor processor of the portable terminal can acquire a location by using a Wi-Fi Positioning System (WPS) method and an indoor positioning method such as a cell IDentifier (ID) method. However, the present exemplary embodiment is not limited to a positioning method using the GPS receiver and the indoor positioning method, and can use various positioning methods.

Meanwhile, if it is determined in operation 202 that the location of the portable terminal is consistent with the predefined location (e.g., home), the sensor processor of the portable terminal proceeds to operation 204 and determines if a terminal motion is sensed during a predetermined time.

If it is determined in operation 204 that the terminal motion is sensed during the predetermined time, the sensor processor of the portable terminal returns to operation 200.

Meanwhile, if it is determined in operation 204 that the terminal motion is not sensed during the predetermined time, the sensor processor of the portable terminal proceeds to operation 206 and determines if a dark state is maintained during a predetermined time. That is, the sensor processor determines if light is measured during a predetermined time through the illumination sensor.

Next, if it is determined in operation 206 that the dark state is not maintained during the predetermined time, i.e., if it is not dark, the sensor processor of the portable terminal returns to operation 200. Meanwhile, if it is determined in operation 206 that the dark state is maintained during the predetermined time, the sensor processor of the portable terminal proceeds to operation 208 and determines if the portable terminal is in a state incapable of sensing with the proximity sensor and illumination sensor of the portable terminal. In the realization, the sensor processor can determine if it is night or day by using a current time provided from an application processor instead of using the sensing result of the illumination sensor.

After that, if it is determined in operation 208 that the portable terminal is in the state incapable of sensing with the proximity sensor and illumination sensor of the portable terminal, the sensor processor of the portable terminal returns to operation 200. Meanwhile, if it is determined in operation 208 that the portable terminal is in a state capable of sensing with the proximity sensor and illumination sensor of the portable terminal, the sensor processor proceeds to operation 210 and recognizes that a user of the portable terminal is in a sleep state.

Next, the sensor processor terminates the procedure of the present exemplary embodiment.

Here, sensing that the user is in the sleep state is to sense whether the electronic device is in a user sleep environment. That is, in FIG. 2A, it is to sense whether, when the electronic device (i.e., portable terminal) is in a preset location, the electronic device is in the user sleep environment. The process of sensing whether the electronic device is the user sleep environment can include a process of sensing through a sensing sensor at least one or more of a motion of the electronic device, illumination around the electronic device, and whether the electronic device has been laid down with its touch screen facing the surface one which the electronic device is laid.

An instruction set for each operation of FIG. 2A can be stored as one or more modules in memories 605 and 670 of FIG. 6. In this case, the modules stored in the memories 605 and 670 can be executed by one or more processors.

FIG. 2B is a flowchart illustrating a method for recognizing a user sleep state in a portable terminal according to a fourth exemplary embodiment of the present invention.

Referring to FIG. 2B, in operation 201, a sensor processor of the portable terminal detects, through a sensor module (e.g., an acceleration sensor, an illumination sensor, and a proximity sensor), a terminal motion, the brightness of light, and whether it is feasible to sense with the proximity sensor and illumination sensor of the portable terminal. For example, the sensor processor senses a motion through the acceleration sensor, senses the amount of surrounding light through the illumination sensor, and senses if an object approaches through the proximity sensor. Also, the portable terminal can detect whether it is feasible to sense with the proximity sensor and illumination sensor of the portable terminal, through the sensing results of the proximity sensor and illumination sensor. Here, a state incapable of sensing with the proximity sensor and illumination sensor of the portable terminal is a state where the portable terminal has been laid down with an LCD screen facing downward, and represents a state where the portable terminal cannot sense because the portable terminal has been laid down in direction in which the proximity sensor and illumination sensor are installed or because the proximity sensor and illumination sensor are in close contact with any object, or a state where the proximity sensor and illumination sensor have not been installed.

According to the realization, the portable terminal determines that it is in a state incapable of sensing with the proximity sensor and illumination sensor of the portable terminal, with only the sensing result of the proximity sensor, i.e., if an object continuously approaches the portable terminal during a predetermined time. According to another realization, the portable terminal can sense if the portable terminal has been laid down with the LCD screen downward, based on the sensing results of a gyroscope sensor and an acceleration sensor. That is, when the proximity sensor and the illumination sensor are installed in a location where the LCD screen is installed, if the portable terminal is laid down with the LCD screen downward, the portable terminal determines that it is in a state incapable of sensing with the proximity sensor and the illumination sensor. In the present exemplary embodiment, a basis for determining whether it is feasible to sense with the proximity sensor and illumination sensor of the portable terminal is not limited to the use of the gyroscope sensor, the acceleration sensor, and the proximity sensor, and can be realized variously by a combination of at least any one or more of the gyroscope sensor, the acceleration sensor, the proximity sensor, and another suitable sensor.

Next, in operation 203, the sensor processor of the portable terminal determines if a location of the portable terminal is consistent with a predefined location (e.g., a home) through a GPS receiver. If it is determined in operation 203 that the location of the portable terminal is not consistent with the predefined location, the sensor processor of the portable terminal returns to operation 201.

According to the realization, in the absence of the GPS receiver, the sensor processor of the portable terminal can acquire a location by using a WPS method and an indoor positioning method such as a cell ID method. However, the present exemplary embodiment is not limited to a positioning method using the GPS receiver and the indoor positioning method, and can use various positioning methods.

After that, if it is determined in operation 203 that the location of the portable terminal is consistent with the predefined location (e.g., home) through the GPS receiver, the sensor processor of the portable terminal proceeds to operation 205.

Next, in operation 205, the sensor processor of the portable terminal determines whether it is feasible to sense with the illumination sensor and the proximity sensor. If it is determined in operation 205 that the portable terminal is in a state incapable of sensing with the illumination sensor and the proximity sensor, the sensor processor of the portable terminal proceeds to operation 207 and deactivates the illumination/proximity sensor. Next, the sensor processor of the portable terminal proceeds to operation 209 and determines if a terminal motion is sensed during a predetermined time. Here, the reason of deactivating the illumination/proximity sensor is for reducing power consumption by deactivating unnecessary sensors. If it is determined in operation 209 that the terminal motion is sensed during the predetermined time, the sensor processor of the portable terminal returns to operation 205. Meanwhile, if it is determined in operation 209 that the terminal motion is not sensed during the predetermined time, the sensor processor of the portable terminal proceeds to operation 213.

Meanwhile, if it is determined in operation 205 that the portable terminal is in a state capable of sensing with the illumination sensor and the proximity sensor, the sensor processor of the portable terminal proceeds to operation 211 and determines if a terminal motion is not sensed during a predetermined time and current brightness sensed through the illumination sensor is equal to or is less than a threshold value. If it is determined in operation 211 that the terminal motion is not sensed during the predetermined time and the current brightness sensed through the illumination sensor is equal to or is less than the threshold value, the sensor processor of the portable terminal proceeds to operation 213 and, otherwise, returns to operation 201.

Next, in operation 213, the sensor processor of the portable terminal recognizes that a user of the portable terminal is in a sleep state.

After that, the sensor processor of the portable terminal terminates the procedure of the present exemplary embodiment.

An instruction set for each operation of FIG. 2A can be stored as one or more modules in memories 605 and 670 of FIG. 6. In this case, the modules stored in the memories 605 and 670 can be executed by one or more processors.

FIG. 2C is a block diagram illustrating an apparatus for recognizing a user sleep state in accordance with the method of FIG. 2A, in the portable terminal according to the third exemplary embodiment of the present invention.

The portable terminal includes a means 250 for determining a location of the portable terminal by using a GPS receiver, and a means 260 for recognizing a sleep state in consideration of a terminal motion, the brightness of light, and whether it is feasible for the portable terminal to sense with an illumination sensor and a proximity sensor according to the location of the portable terminal. According to the realization, in the absence of the GPS receiver, the portable terminal can acquire a location by using a WPS method and an indoor positioning method such as a cell ID method. However, the present exemplary embodiment is not limited to a positioning method using the GPS receiver and the indoor positioning method, and can use various positioning methods.

According to another realization, by using a preset alarm time, the portable terminal may initiate sleep state awareness according to the methods of FIG. 1A to FIG. 2B, from before the preset alarm time. For example, when a user sets an alarm time as 6:00 a.m., the portable terminal may initiate the sleep state aware from six hours ago (i.e., from 24:00). As such, the sleep state awareness can be embodied by a combination of a set alarm time, location recognition, an acceleration sensor, an illumination sensor, a proximity sensor and the like.

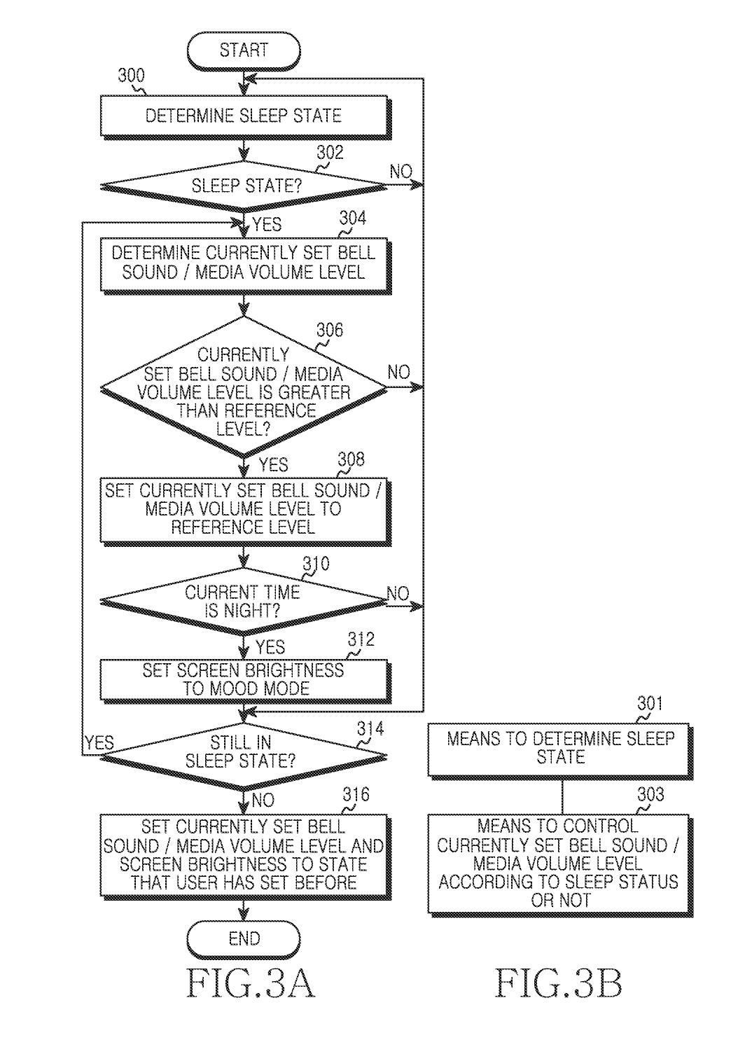

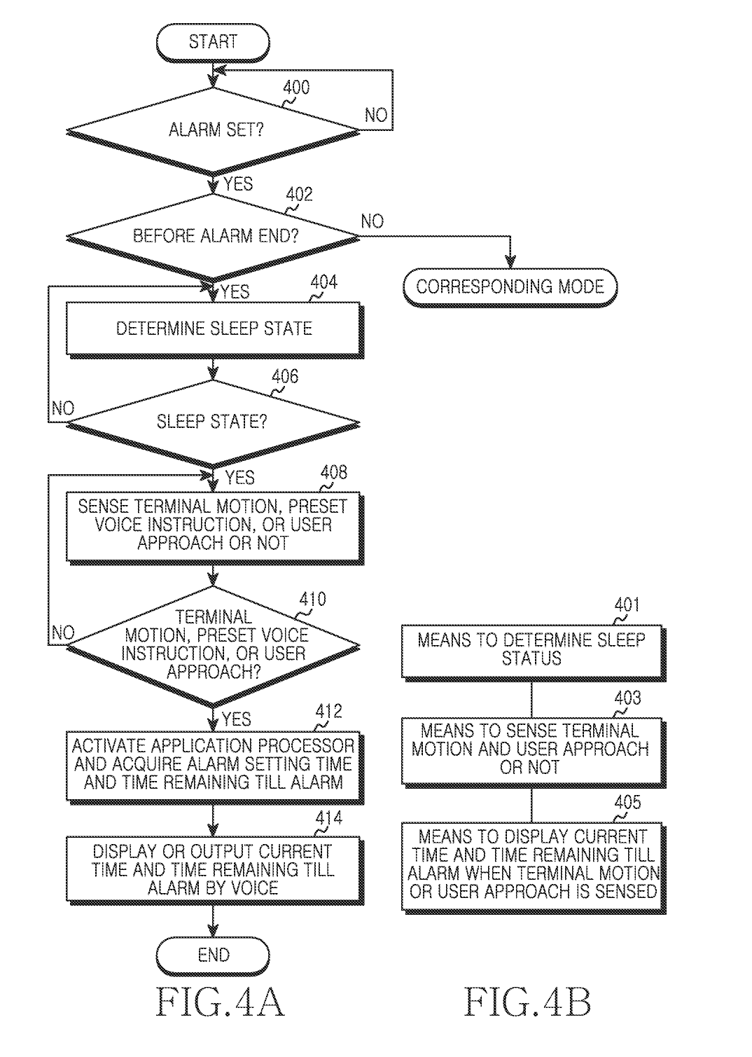

FIG. 3A is a flowchart illustrating a method for providing a sound sleep service after sleep state recognition in a portable terminal according to a fifth exemplary embodiment of the present invention.

Referring to FIG. 3A, in operation 300, a sensor processor of the portable terminal determines if a user is in a sleep state according to the method of FIGS. 1A, 1B, 2A or 2B.

After that, when the user is in the sleep state in operation 302, the sensor processor proceeds to operation 304 and determines a currently set bell sound/media volume/audio volume level.

If the currently set bell sound/media volume/audio volume level is not greater than a reference level (for example, mute, or volume level =0) in operation 306, the sensor processor returns to operation 300.

Meanwhile, if the currently set bell sound/media volume/audio volume level is greater than the reference level in operation 306, the sensor processor proceeds to operation 308 and sets the currently set bell sound/media volume/audio volume level to the reference level.

Next, the sensor processor proceeds to operation 310 and determines whether a current time is night. In the realization, the sensor processor can determine whether it is night or day on the basis of the amount of light measured through an illumination sensor.

If it is determined in operation 310 that the current time is night, the sensor processor proceeds to operation 312 and sets the brightness of an LCD screen to a mood mode. The mood mode refers to a screen brightness state where a user has no dazzling although he/she stares at the LCD screen at night. Meanwhile, if it is determined in operation 310 that the current time is not night, the sensor processor returns to operation 300. According to the realization, if it is determined in operation 310 that the current time is not the night, the sensor processor can return to operation 314.

After that, in operation 314, the sensor processor determines whether the user of the portable terminal is still in the sleep state. If the user is still in the sleep state in operation 314, the sensor processor returns to operation 304. Meanwhile, if the user is no longer in the sleep state in operation 314, the sensor processor proceeds to operation 316 and sets the currently set bell sound/media volume level and the screen brightness to a state that the user has set before the sleep state.

After that, the sensor processor terminates the procedure of the present exemplary embodiment.

Here, sensing that the user is in the sleep state is to sense whether the electronic device is a user sleep environment.

An instruction set for each operation of FIG. 3A can be stored as one or more modules in memories 605 and 670 of FIG. 6. In this case, the modules stored in the memories 605 and 670 can be executed by one or more processors.

FIG. 3B is a block diagram illustrating an apparatus for providing a sound sleep service in accordance with the method of FIG. 3A, in a portable terminal according to the fifth exemplary embodiment of the present invention.

A sensor processor of the portable terminal includes a means 301 for recognizing a user sleep state according to the methods of FIGS. 1A, 1B, 2A or 2B, and a means 303 for controlling a currently set bell sound/media volume/audio volume level depending on a sleep state or not. For example, when the currently set bell sound/media volume/audio volume level is greater than a reference level, the portable terminal sets the currently set bell sound/media volume/audio volume level to the reference level and, when a current time is night, the portable terminal sets LCD screen brightness to a screen brightness state (e.g., a mood mode state) in which a user has no dazzling although he/she stares at an LCD screen. And, if the user wakes up in the sleep state, the portable terminal changes the bell sound/media volume level and the screen brightness into a state that the user has set before the sleep state.

As described above, in FIGS. 3A and 3B, if a portable terminal enters a sleep mode by setting an audio volume of the portable terminal such as a bell sound/media volume to ‘0’ after recognizing that a user is in a sleep state, the user can have a sound sleep without disturbance by a bell sound for call or text message reception. And, if a current time is night, a preset screen brightness can be set slightly dark although having been set manually, such that eyes are not strained when the user turns on a screen at midnight. In the sleep mode, if the user wakes up, the audio sound of the portable terminal and the screen brightness are automatically converted into values that the user has previously set.

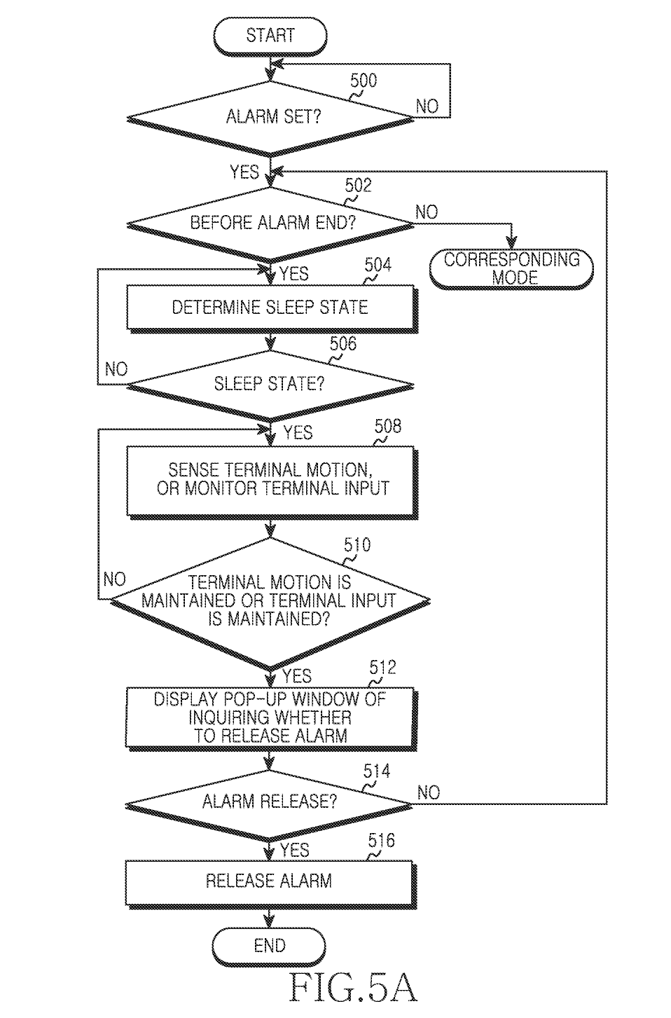

FIG. 4A is a flowchart illustrating a method for providing a sound sleep service after sleep state recognition in a portable terminal according to a sixth exemplary embodiment of the present invention.

Referring to FIG. 4A, when alarm setting has been done in operation 400, a sensor processor of the portable terminal proceeds to operation 402 and determines if it is before alarm end. If it is before the alarm end, the sensor processor proceeds to operation 404 and meanwhile, if it is after the alarm end, the sensor processor performs a corresponding mode.

In operation 404, the sensor processor of the portable terminal determines if a user is in a sleep state according to the methods of FIGS. 1A, 1B, 2A or 2B.

Next, when the user is in the sleep state in operation 406, the sensor processor of the portable terminal proceeds to operation 408 and, otherwise, the sensor processor returns to operation 404.

In operation 408, the sensor processor of the portable terminal senses a terminal motion through an acceleration sensor, or detects a preset voice instruction, or senses if the user approaches the portable terminal through a proximity sensor.

Next, when sensing the terminal motion, or detecting the preset voice instruction, or sensing if the user approaches the portable terminal in operation 410, the sensor processor proceeds to operation 412 and activates an application processor and determines an alarm setting time and a time remaining until the alarm time. The reason the sensor processor activates the application processor is that alarm function control is performed by the application processor. Meanwhile, the sensor processor deactivates the application processor after determining the alarm setting time and the time remaining until the alarm time.

After that, in operation 414, the sensor processor displays or outputs a current time and the time remaining until the alarm time by voice through a speaker. In the realization, after the sensor processor activates the application processor, the application processor may determine the alarm setting time and the time remaining until the alarm time to display or output by voice.

Next, the sensor processor terminates the procedure of the present exemplary embodiment.

In other words, in a state where alarm has been set, the portable terminal that is an electronic device recognizes a first state (i.e., a user sleep state) through a sensor module and, if sensing a second state while the first state is maintained (i.e., in a case of portable terminal motion sensing, preset voice instruction detecting, or user approach sensing and the like in the user sleep state), the sensor processor of the portable terminal activates the application processor of the portable terminal being in a deactivation state. The application processor controls data output. The activated application processor outputs a time remaining until an alarm time or/and a current time. The time remaining until the alarm time or/and the current time are displayed on a display (i.e., a touch screen) of the portable terminal or are output by sound through the speaker. After that, the activated application processor can be again deactivated. Here, the user sleep state can represent that a surrounding state of the portable terminal is a sleep state. Also, the portable terminal motion sensing is to sense a motion of the portable terminal itself Also, the preset voice instruction detecting is to receive a voice input corresponding to a voice instruction set to the portable terminal. Also, the user approach sensing represents sensing that the user approaches the portable terminal, and means that the portable terminal senses an object approaching the portable terminal.

That is, if the portable terminal that is the electronic device senses a predetermined surrounding state in a predetermined function setting state (e.g., an alarm setting state), the sensor processor activates the application processor (controlling data output) that is in the deactivation state, and the activated application processor controls to display or output set predetermined function related information (e.g., a time remaining until an alarm time) by voice. Here, the activated application processor can be again deactivated.

In other words, if the portable terminal that is the electronic device senses a predetermined state through a sensor module in the predetermined function setting state (e.g., the alarm setting state) (i.e., in a case of terminal motion sensing, preset voice instruction detecting, or user approach sensing and the like in the user sleep state), the sensor processor activates the application processor that is in the deactivation state, and the activated application processor displays or outputs information associated with the set function by voice.

An instruction set for each operation of FIG. 4A can be stored as one or more modules in memories 605 and 670 of FIG. 6. In this case, the modules stored in the memories 605 and 670 can be executed by one or more processors.

FIG. 4B is a block diagram illustrating an apparatus for providing a sound sleep service in accordance with the method of FIG. 4A, in a portable terminal according to the sixth exemplary embodiment of the present invention.

The portable terminal includes a means 401 for recognizing a user sleep state according to the methods of FIGS. 1A, 1B, 2A or 2B, a means 403 for sensing a terminal motion by using an acceleration sensor and sensing user approach or not by using a proximity sensor, and a means 405 for, when the terminal motion or the user approach is sensed, displaying or outputting a current time and a time remaining until an alarm time by voice.

As described above, in FIGS. 4A and 4B, if the user comes into action on the portable terminal through the acceleration sensor or the proximity sensor after the portable terminal recognizes the user sleep state, the portable terminal activates the application processor, determines a preset alarm time and a time remaining from a current time to the alarm time, and displays or provides the current time and the time remaining until the alarm time by voice.

Here, if an erroneous operation is worried, the user may previously register a pattern of a terminal motion (for example, motions of tapping the terminal one time in a state where the terminal is put on a table, shaking the terminal, lifting the terminal and the like), and activate the application processor to perform an alarm service when the registered pattern is input. And, when setting alarm, the user can optionally register or set a motion pattern for activating the application processor.

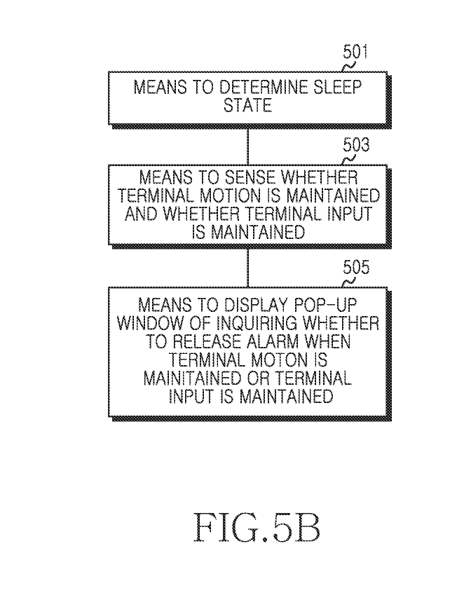

FIG. 5A is a flowchart illustrating a method for providing a sound sleep service after sleep state recognition in a portable terminal according to a seventh exemplary embodiment of the present invention.

Referring to FIG. 5A, when alarm setting has been done in operation 500, a sensor processor of the portable terminal proceeds to operation 502 and determines if it is before alarm end. If it is before the alarm end, the sensor processor proceeds to operation 504 and meanwhile, if it is after the alarm end, the sensor processor performs a corresponding mode.

In operation 504, the sensor processor of the portable terminal determines if a user is in a sleep state according to the methods of FIGS. 1A, 1B, 2A or 2B.

Next, when the user is in the sleep state in operation 506, the sensor processor of the portable terminal proceeds to operation 508 and, otherwise, the sensor processor returns to operation 504.

In operation 508, the sensor processor of the portable terminal senses a terminal motion through an acceleration sensor during a predetermined time, or monitors a terminal input such as preset voice instruction or soft key input during a predetermined time.

After that, when sensing the terminal motion during the predetermined time or sensing the terminal input during the predetermined time in operation 510, the sensor processor proceeds to operation 512 and determines that a user wakes up in the sleep state and comes into action, and displays a pop-up window for inquiring alarm release or non-release. At this time, when displaying the pop-up window, the sensor processor can display it together with various animation effects.

Next, if the alarm release is selected by the user in operation 514, the sensor processor proceeds to operation 516 and activates an application processor to transmit an alarm release request. Then, the activated application processor releases a preset alarm.

Meanwhile, if the alarm release is not selected by the user in operation 514, the sensor processor returns to operation 502 and holds preset alarm setting.

After that, the sensor processor terminates the procedure of the present exemplary embodiment.

Here, sensing that the user is in the sleep state is to sense whether a surrounding state of an electronic device is a sleep state. A process of sensing whether the surrounding state is the sleep state includes a process of sensing at least one or more of a motion of the portable terminal, illumination around the portable terminal, and whether the portable terminal has been laid down with its touch screen facing the bottom.

An instruction set for each operation of FIG. 5A can be stored as one or more modules in memories 605 and 670 of FIG. 6. In this case, the modules stored in the memories 605 and 670 can be executed by one or more processors.

FIG. 5B is a block diagram illustrating an apparatus for providing a sound sleep service in accordance with the method of FIG. 5A, in a portable terminal according to the seventh exemplary embodiment of the present invention.

The portable terminal includes a means 501 for recognizing a user sleep state according to the methods of FIGS. 1A, 1B, 2A or 2B, a means 503 for sensing a terminal motion during a predetermined time through an acceleration sensor and monitoring a terminal input during a predetermined time, and a means 505 for, when the terminal motion is maintained or the terminal input is maintained, displaying a pop-up window for inquiring alarm release or non-release. According to the realization, without displaying the pop-up window, the portable terminal can release a set alarm.

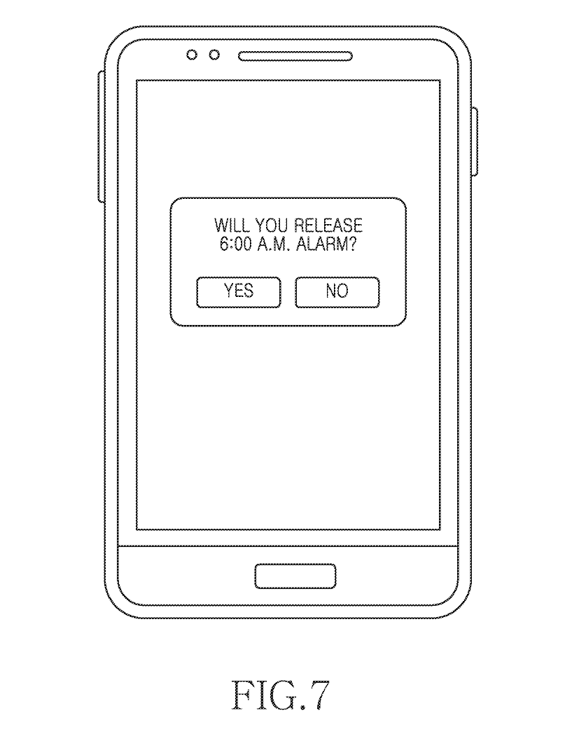

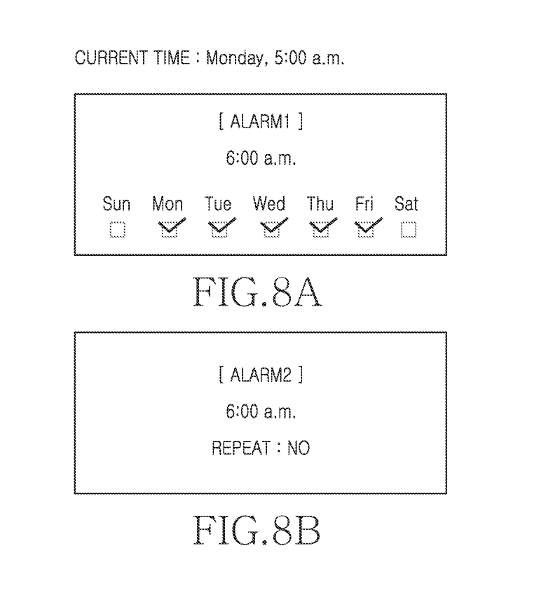

As described above, in FIGS. 5A and 5B an alarm is released after recognizing a sleep state. If a current time is later than a preset alarm time, the alarm is undoubtedly released. But, if the current time is earlier than the preset alarm time, when a terminal motion is continuously sensed or a user input (e.g., a touch and the like) is continuously done, a pop-up window for inquiring a user's intention about whether to release a currently set alarm is floated on a screen as in FIG. 7 below. At this time, if the user wants the release to select “YES”, the alarm is released as in FIG. 8 below.

FIG. 6 illustrates a construction of an electronic device according to an exemplary embodiment of the present invention.

Referring to FIG. 6, the electronic device can be a portable electronic device, and can be a device such as a portable terminal, a mobile phone, a mobile pad, a media player, a tablet computer, a handheld computer, or a Personal Digital Assistant (PDA). Also, the electronic device may be any portable electronic device including a device having a combination of two or more functions among these devices.

The electronic device includes a controller 600, a speaker/microphone 610, a camera 620, a GPS receiver 630, a Radio Frequency (RF) processor 640, a sensor module 650, a touch screen 660, a touch screen controller 665, and an external memory 670.

The controller 600 can include an interface 601, one or more processors 602, 603, and 604, and an internal memory 605. According to various cases, the whole controller 600 is also called a processor. The interface 601, the application processor 602, the communication processor 603, and the internal memory 605 can be separate constituent elements or can be integrated in one or more integrated circuits.

The processors 602 and 604 execute various software programs to perform various functions for the electronic device. The communication processor 603 performs processing and control for voice communication and data communication. Also, further to this general function, the processors 602, 603, and 604 may play a role of executing a specific software module (i.e., an instruction set) stored in the external memory 670 or internal memory 605 to perform specific various functions corresponding to the software module. That is, the processors 602, 603, and 604 interwork with the software modules stored in the external memory 670 or internal memory 605 to carry out a method of an exemplary embodiment of the present invention.

In the first exemplary embodiment of the present invention, the sensor processor 604 detects through the sensor module 650 a terminal motion, the brightness of light, and whether it is feasible to sense with the proximity sensor and illumination sensor of the portable terminal and, when the terminal motion is not sensed during a predetermined time, determines if a dark state is maintained during a predetermined time. When the dark state is maintained during the predetermined time, the sensor processor 604 determines whether the portable terminal is in a state incapable of sensing with the proximity sensor and illumination sensor of the portable terminal. In the realization, the sensor processor 604 can determine if it is night or day by using a current time provided from the application processor 602 instead of using the sensing result of the illumination sensor. Also, when the portable terminal is in a state capable of sensing with the proximity sensor and illumination sensor of the portable terminal, the sensor processor 604 recognizes that a user of the portable terminal is in a sleep state.

In the second exemplary embodiment of the present invention, the sensor processor 604 detects through the sensor module 650 a terminal motion, the brightness of light, and whether it is feasible to sense with the proximity sensor and illumination sensor of the portable terminal, and determines whether it is feasible to sense with the illumination sensor and the proximity sensor and, when the portable terminal is in a state incapable of sensing with the illumination sensor and the proximity sensor, deactivates the illumination/proximity sensor, and the sensor processor 604 of the portable terminal determines if the terminal motion is sensed during a predetermined time and, when the terminal motion is not sensed during the predetermined time, the sensor processor 604 of the portable terminal recognizes that the user of the portable terminal is in the sleep state. Also, when the portable terminal is in a state capable of sensing with the illumination sensor and the proximity sensor, the sensor processor 604 determines if the terminal motion is not sensed during the predetermined time and current brightness sensed through the illumination sensor is equal to or is less than a threshold value and, when the terminal motion is not sensed during the predetermined time and the current brightness sensed through the illumination sensor is equal to or is less than the threshold value, recognizes that the user of the portable terminal is in the sleep state.

In the third exemplary embodiment of the present invention, the sensor processor 604 senses through the sensor module 650 a terminal motion, the brightness of light, and whether it is feasible to sense with the proximity sensor and illumination sensor of the portable terminal, and determines if a location of the portable terminal is consistent with a predefined location (e.g., home) through the GPS receiver 630 and, when the location of the portable terminal is consistent with the predefined location, determines if the terminal motion is sensed during a predetermined time. And, when the terminal motion is sensed during the predetermined time, the sensor processor 604 determines if a dark state is maintained during a predetermined time and, when the dark state is maintained during the predetermined time, the sensor processor 604 determines if the portable terminal is in a state incapable of sensing with the proximity sensor and illumination sensor of the portable terminal and, when the portable terminal is in a state capable of sensing with the proximity sensor and illumination sensor of the portable terminal, recognizes that the user of the portable terminal is in the sleep state.

In the fourth exemplary embodiment of the present invention, the sensor processor 604 detects through the sensor module 650 a terminal motion, the brightness of light, and whether it is feasible to sense with the proximity sensor and illumination sensor of the portable terminal, and determines if a location of the portable terminal is consistent with a predefined location through the GPS receiver 630 and, when the location of the portable terminal is consistent with the predefined location, determines whether it is feasible to sense with the illumination sensor and proximity sensor and, when the portable terminal is in a state incapable of sensing with the illumination sensor and the proximity sensor, the sensor processor 604 deactivates the illumination/proximity sensor, and the sensor processor 604 of the portable terminal determines whether the terminal motion is sensed during a predetermined time and, when the terminal motion is not sensed during the predetermined time, recognizes that the user of the portable terminal is in the sleep state. Also, when the portable terminal is in a state capable of sensing with the illumination sensor and the proximity sensor, the sensor processor 604 determines if the terminal motion is not sensed during the predetermined time and current brightness sensed through the illumination sensor is equal to or is less than a threshold value and, when the terminal motion is not sensed during the predetermined time and the current brightness sensed through the illumination sensor is equal to or is less than the threshold value, the sensor processor 604 recognizes that the user of the portable terminal is in the sleep state.

In the fifth exemplary embodiment of the present invention, the sensor processor 604 determines if the user is in the sleep state according to the first to fourth exemplary embodiments and, when the user is in the sleep state, the sensor processor 604 determines a currently set bell sound/media volume/audio volume level and, when the currently set bell sound/media volume/audio volume level is greater than a reference level, sets the currently set bell sound/media volume/audio volume level to the reference level. Also, the sensor processor 604 determines whether a current time is night and, when the current time is night, the sensor processor 604 sets LCD screen brightness to a mood mode. The mood mode refers to a screen brightness state in which the user has no dazzling even when he/she stares at an LCD screen at night. And, the sensor processor 604 determines if the user of the portable terminal is still in the sleep state and, when the user is no longer in the sleep state, sets a bell sound/media volume level and screen brightness to a state that the user has set before the sleep state. According to the realization, the bell sound/media volume level adjustment and the screen brightness adjustment can be performed by the application processor 602 after the sensor processor 604 activates the application processor 602.

In the sixth exemplary embodiment of the present invention, when alarm setting has been done, the sensor processor 604 determines if it is before alarm end and, when it is before the alarm end, determines if the user is in the sleep state according to the first to fourth exemplary embodiments and, when the user is in the sleep state, senses a terminal motion through an acceleration sensor, or detects a preset voice instruction, or senses if the user approaches the portable terminal through a proximity sensor and, when sensing the terminal motion, or detecting the preset voice instruction, or sensing that the user approaches, activates the application processor 602, determines an alarm setting time and a time remaining until the alarm time, and displays or outputs a current time and the time remaining until the alarm time by voice through a speaker. In the realization, after the sensor processor 604 activates the application processor 602, the application processor 602 may determine the alarm setting time and the time remaining until the alarm time to display or output by voice. That is, if the sensor processor 604 senses a predetermined state (i.e., terminal motion sensing, preset voice instruction detection or user approach sensing and the like) through the sensor module 650 in an alarm setting state, the sensor processor 604 activates the application processor 602 that is in a deactivation state, and displays or outputs the time remaining until the alarm time by voice. That is, if the sensor processor 604 senses a predetermined state in a state where a predetermined function is set (i.e., in the alarm setting state), the sensor processor 604 activates the application processor 602 that is in the deactivation state (the application processor 602 taking charge of a data output function), and the activated application processor 602 displays or outputs set predetermined function related information (i.e., a current time, a time remaining until an alarm time and the like) by voice. Here, the activated application processor 602 can be again deactivated.

In the seventh exemplary embodiment of the present invention, when alarm setting has been done, the sensor processor 604 determines if it is before alarm end and, when it is before the alarm end, determines if the user is in the sleep state according to the first to fourth exemplary embodiments and, when the user is in the sleep state, senses a terminal motion during a predetermined time through an acceleration sensor, or monitors a terminal input such as preset voice instruction and soft key input during a predetermined time and, when sensing the terminal motion during the predetermined time or sensing the terminal input during the predetermined time, determines that the user wakes up in the sleep state to come into action, and displays a pop-up window for inquiring alarm release or non-release. At this time, when displaying the pop-up window, the sensor processor 604 can display it together with various animation effects. Also, when the alarm release is selected by the user, the sensor processor 604 activates the application processor 602 to transmit an alarm release request. Then, the activated application processor 602 releases a preset alarm. When the alarm release is not selected by the user, the preset alarm setting is maintained.

On the other hand, another processor (not shown) can include one or more data processors, image processors, or COders/DECoders (CODECS). The data processor, the image processor, or the CODEC may be constructed separately. Or, the data processor, the image processor, or the CODEC may be constructed as several processors performing different functions. The interface 601 is connected to the touch screen controller 665 of the electronic device and the external memory 670 thereof

The sensor module 650 can be coupled to the interface 601 to make various functions possible. For instance, a motion sensor and an optical sensor can be coupled to the interface 601 to sense a motion of the electronic device and sense a light from the exterior, respectively. Besides this, a positioning system and other sensors such as a temperature sensor, a biological sensor and the like can be connected to the interface 601 to perform their related functions.

Further, the sensor module 650 continuously senses if the portable terminal is in a state of being in motion or in a state of being in no motion, senses the brightness of current space by using an illumination sensor, and senses if an object approaches the portable terminal by using a proximity sensor.

The camera 620 can be coupled with the sensor module 650 through the interface 601 to perform a camera function such as photo and video clip recording.

The RF processor 640 performs a communication function. For example, under the control of the communication processor 603, the RF processor 640 converts an RF signal into a baseband signal and provides the baseband signal to the communication processor 603, or converts a baseband signal from the communication processor 603 into an RF signal and transmits the RF signal. Here, the communication processor 603 processes the baseband signal in various communication methods. For example, the communication method can include, though not limited to, a Global System for Mobile Communication (GSM) communication method, an Enhanced Data GSM Environment (EDGE) communication method, a Code Division Multiple Access (CDMA) communication method, a Wireless-Code Division Multiple Access (W-CDMA) communication method, a Long Term Evolution (LTE) communication method, an Orthogonal Frequency Division Multiple Access (OFDMA) communication method, a Wireless Fidelity (Wi-Fi) communication method, a WiMAX communication method or/and a Bluetooth communication method.

The speaker/microphone 610 can take charge of input and output of an audio stream such as voice recognition, voice replication, digital recording and telephone function. That is, the speaker/microphone 610 converts a voice signal into an electrical signal, or converts an electrical signal into a voice signal. Although not illustrated, detachable ear phone, head phone or head set can be connected to the electronic device through an external port.

The touch screen controller 665 can be coupled to the touch screen 660. The touch screen 660 and the touch screen controller 665 can detect a touch and a motion or an interruption of them, by using, although not limited to, not merely capacitive, resistive, infrared and surface acoustic wave technologies for determining one or more touch points with the touch screen 660 but also any multi-touch sensing technology including other proximity sensor arrays or other elements.

The touch screen 660 provides an input/output interface between the electronic device and a user. That is, the touch screen 660 forwards a user's touch input to the electronic device. Also, the touch screen 660 is a medium for showing to the user an output of the electronic device. That is, the touch screen 660 shows to the user a visual output. This visual output is displayed in a form of a text, a graphic, a video and a combination of them.

In the present exemplary embodiment, when the electronic device outputs an alarm release pop-up window or outputs a current time and a time remaining until an alarm time, this can be done through a screen. This screen can be a touch screen processing a touch input as well.

The touch screen 660 can be various displays. For instance, the touch screen 660 can be, although not limited to, a Liquid Crystal Display (LCD), a Light Emitting Diode (LED), a Light emitting Polymer Display (LPD), an Organic Light Emitting Diode (OLED), an Active Matrix Organic Light Emitting Diode (AMOLED) or a Flexible LED (FLED).

The GPS receiver 630 converts signals received from three artificial satellites into information of a location, a speed, an hour and the like. For instance, the GPS receiver 630 determines distances between the artificial satellites and the GPS receiver 630 through a multiplication of the speed of light and signal arrival time, obtains accurate locations and distances of the artificial satellites, and measures a location of the electronic device in accordance with the known triangulation principle.

According to the realization, in the absence of the GPS receiver 630 in the electronic device, the electronic device can acquire location information by using a WPS method and an indoor positioning method such as a cell ID method. However, the present exemplary embodiment is not limited to a positioning method using the GPS receiver and the indoor positioning method, and can use various positioning methods.

The external memory 670 or the internal memory 605 can include high-speed random access memory and/or non-volatile memory such as one or more magnetic disk storage devices, one or more optical storage devices, and/or flash memory (for example, NAND, NOR).

The external memory 670 or the internal memory 605 stores software. A software constituent element includes an Operating System (OS) software module, a communication software module, a graphical software module, a user interface software module, a Moving Picture Experts Group (MPEG) module, a camera software module, one or more application software modules and the like. Also, the module, a software constituent element, can be expressed as a set of instructions. Therefore, the module is also expressed as an instruction set. The module is also expressed as a program.

The OS software includes various software constituent elements controlling general system operation. This control of the general system operation means, for example, memory management and control, storage hardware (device) control and management, power control and management and the like. The OS software performs even a function of making smooth communication between various hardware (devices) and software constituent elements (modules).

The communication software module enables communication with other electronic devices, such as a personal computer, a server and/or a portable terminal and the like, through the RF processor 640. And, the communication software module is constructed in a protocol structure corresponding to a corresponding communication method.

The graphical software module includes various software constituent elements for providing and displaying a graphic on the touch screen 660. The term ‘graphic’ is used as meaning including a text, a web page, an icon, a digital image, a video, an animation and the like.

The user interface software module includes various software constituent elements associated with a user interface. The user interface software module includes information about how a state of the user interface is changed or in which conditions the change of the state of the user interface is carried out, and the like.

The camera software module includes a camera-related software constituent element enabling camera related processes and functions. The application module includes a browser, an electronic mail (e-mail), an instant message, word processing, keyboard emulation, an address book, a touch list, a widget, Digital Right Management (DRM), voice recognition, voice replication, a position determining function, a location based service and the like. The memories 670 and 605 can include additional modules (i.e., instructions) besides the modules mentioned above. Or, the memories 670 and 605 may not use some modules (i.e., instructions) according to need.

In relation to the present exemplary embodiment, the application module includes an instruction of detecting through the sensor module 650 a terminal motion, the brightness of light, and whether it is feasible to sense with the proximity sensor and illumination sensor of the portable terminal and, when the terminal motion is not sensed during a predetermined time, determining if a dark state is maintained during a predetermined time and, when the dark state is maintained during the predetermined time, determining whether the portable terminal is in a state incapable of sensing with the proximity sensor and illumination sensor of the portable terminal. In the realization, the application module can include an instruction of determining if it is night or day by using a current time provided from the application processor 602 instead of using the sensing result of the illumination sensor. Also, the application module includes an instruction of, when the portable terminal is in a state capable of sensing with the proximity sensor and illumination sensor of the portable terminal, recognizing that a user of the portable terminal is in a sleep state.

In the second exemplary embodiment of the present invention, the application module includes an instruction of detecting through the sensor module 650 a terminal motion, the brightness of light, and whether it is feasible to sense with the proximity sensor and illumination sensor of the portable terminal, and determining whether it is feasible to sense with the illumination sensor and the proximity sensor and, when the portable terminal is in a state incapable of sensing with the illumination sensor and the proximity sensor, deactivating the illumination/proximity sensor, and determining if the terminal motion is sensed during a predetermined time and, when the terminal motion is not sensed during the predetermined time, recognizing that the user of the portable terminal is in the sleep state. Also, the application module further includes an instruction of, when the portable terminal is in a state capable of sensing with the illumination sensor and the proximity sensor, determining if the terminal motion is not sensed during the predetermined time and current brightness sensed through the illumination sensor is equal to or is less than a threshold value and, when the terminal motion is not sensed during the predetermined time and the current brightness sensed through the illumination sensor is equal to or is less than the threshold value, recognizing that the user of the portable terminal is in the sleep state.

In the third exemplary embodiment of the present invention, the application module includes an instruction of sensing through the sensor module 650 a terminal motion, the brightness of light, and whether it is feasible to sense with the proximity sensor and illumination sensor of the portable terminal, and determining if a location of the portable terminal is consistent with a predefined location (e.g., home) through the GPS receiver 630 and, when the location of the portable terminal is consistent with the predefined location, determining if the terminal motion is sensed during a predetermined time. And, the application module further includes an instruction of, when the terminal motion is sensed during the predetermined time, determining if a dark state is maintained during a predetermined time and, when the dark state is maintained during the predetermined time, determining if the portable terminal is in a state incapable of sensing with the proximity sensor and illumination sensor of the portable terminal and, when the portable terminal is in a state capable of sensing with the proximity sensor and illumination sensor of the portable terminal, recognizing that the user of the portable terminal is in the sleep state.

In the fourth exemplary embodiment of the present invention, the application module includes an instruction of detecting through the sensor module 650 a terminal motion, the brightness of light, and whether it is feasible to sense with the proximity sensor and illumination sensor of the portable terminal, and determining if a location of the portable terminal is consistent with a predefined location through the GPS receiver 630 and, when the location of the portable terminal is consistent with the predefined location, determining whether it is feasible to sense with the illumination sensor and proximity sensor and, when the portable terminal is in a state incapable of sensing with the illumination sensor and the proximity sensor, deactivating the illumination/proximity sensor, and determining whether the terminal motion is sensed during a predetermined time and, when the terminal motion is not sensed during the predetermined time, recognizing that the user of the portable terminal is in the sleep state. Also, the application module further includes an instruction of, when the portable terminal is in a state capable of sensing with the illumination sensor and the proximity sensor, determining if the terminal motion is not sensed during the predetermined time and current brightness sensed through the illumination sensor is equal to or is less than a threshold value and, when the terminal motion is not sensed during the predetermined time and the current brightness sensed through the illumination sensor is equal to or is less than the threshold value, recognizing that the user of the portable terminal is in the sleep state.

In the fifth exemplary embodiment of the present invention, the application module determines if the user is in the sleep state according to the first to fourth exemplary embodiments and, when the user is in the sleep state, determines a currently set bell sound/media volume/audio volume level and, when the currently set bell sound/media volume/audio volume level is greater than a reference level, sets the currently set bell sound/media volume/audio volume level to the reference level. Also, the application module includes an instruction of determining whether a current time is night and, when the current time is night, setting LCD screen brightness to a mood mode. The mood mode means a screen brightness state in which the user has no dazzling even when he/she stares at an LCD screen at night. And, the application module further includes an instruction of determining if the user of the portable terminal is still in the sleep state and, when the user is no longer in the sleep state, setting a bell sound/media volume level and screen brightness to a state that the user has set before the sleep state.

In the sixth exemplary embodiment of the present invention, the application module includes an instruction of, when alarm setting has been done, determining if it is before alarm end and, when it is before the alarm end, determining if the user is in the sleep state according to the first to fourth exemplary embodiments and, when the user is in the sleep state, sensing a terminal motion through an acceleration sensor, or detecting a preset voice instruction, or sensing if the user approaches the portable terminal through a proximity sensor and, when sensing the terminal motion, or detecting the preset voice instruction, or sensing that the user approaches, activating the application processor 602, determining an alarm setting time and a time remaining until the alarm time, and displaying or outputting a current time and the time remaining until the alarm time by voice through a speaker. In the realization, the application module includes an instruction of, after activating the application processor 602, determining the alarm setting time and the time remaining until the alarm time to display or output by voice.

In the seventh exemplary embodiment of the present invention, when alarm setting has been done, the application module determines if it is before alarm end and, when it is before the alarm end, determines if the user is in the sleep state according to the first to fourth exemplary embodiments and, when the user is in the sleep state, senses a terminal motion during a predetermined time through an acceleration sensor, or monitors a terminal input such as preset voice instruction and soft key input during a predetermined time and, when sensing the terminal motion during the predetermined time or sensing the terminal input during the predetermined time, determines that the user wakes up in the sleep state to come into action, and displays a pop-up window for inquiring alarm release or non-release. At this time, when displaying the pop-up window, the application module can display it together with various animation effects. Also, the application module includes an instruction of, when the alarm release is selected by the user, activating the application processor 602 to transmit an alarm release request, and allowing the activated application processor 602 to release a preset alarm. When the alarm release is not selected by the user, the preset alarm setting is maintained.

Also, various functions of the electronic device according to the exemplary embodiments of the present invention mentioned above or to be mentioned below can be executed by hardware including one or more processing and/or Application Specific Integrated Circuits (ASICs), and/or software, and/or a combination of them.

FIG. 7 illustrates an alarm release pop-up window according to an exemplary embodiment of the present invention.

As illustrated in FIG. 7, when alarm has been set to 6:00 a.m., a pop-up window inquiring whether to release the preset alarm of 6:00 a.m. is displayed in the alarm release pop-up window.

FIGS. 8A and 8B are diagrams illustrating an example of alarm release setting according to an exemplary embodiment of the present invention.

Referring to FIGS. 8A and 8B, if “YES” is selected in FIG. 7, a screen of FIG. 8A or FIG. 8B is displayed such that a user can release repeated weekday alarms or release only a Today alarm corresponding to a present day.

For example, in a case where a user has set repeated alarms of 6:00 a.m. of weekdays (Monday, Tuesday, Wednesday, Thursday, Friday), the preset repeated alarms are not all released but only a Today alarm corresponding to a present day is released (FIG. 8A). According to the realization, the preset repeated alarms can be all released. And, in a case where the user has set a Today alarm of 6:00 a.m. with no repetition, the preset Today alarm with no repetition is released (FIG. 8B).

As described above, exemplary embodiments of the present invention have an advantage of being capable of performing control such that a user does not suffer the disruption of sleep from an audio sound of a portable terminal such as a bell sound/media sound and the like by performing various context awareness, particularly, recognizing a user sleep state through an acceleration sensor, a proximity sensor, and an illumination sensor at low power based on an SSP and also, being capable of minimizing user's dazzling by automatically adjusting the brightness of a screen.

Also, the exemplary embodiments of the present invention have an advantage of being capable of releasing an unnecessary alarm because recognizing a case where, before a preset alarm goes off, a user already wakes up or comes into other action.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An operation method of an electronic device, the method comprising:
in a state where a predetermined function has been set, sensing a first state through a sensing module by control of a first processor;
activating, by the first processor, a second processor which is in a deactivation state; and
outputting predetermined function related information by control of the activated second processor.

2. The method of claim 1, wherein the predetermined function comprises an alarm function, and the first state comprises a state in which, while the electronic device is maintained in a user sleep environment, at least one of a motion of the electronic device is detected, a preset voice is input, and an object approaching the electronic device is sensed.

3. The method of claim 2, wherein the first processor comprises a sensor processor, and the second processor comprises an application processor controlling data output, and the predetermined function related information comprises at least one of a time remaining until an alarm time and a current time.

4. The method of claim 3, further comprising deactivating the activated application processor.

5. The method of claim 3, wherein at least one of the time remaining until the alarm time and the current time is displayed on a touch screen of the electronic device or is outputted by sound through a speaker of the electronic device.

6. An electronic device comprising:
one or more processors configured to execute one or more computer executable instructions;
a memory configured to store data and the one or more computer executable instructions,
wherein the one or more computer executable instructions comprise one or more computer executable instructions for, in a state where a predetermined function has been set, sensing a first state through a sensing module by control of a first processor, activating, by the first processor, a second processor that is in a deactivation state, and outputting predetermined function related information by control of the activated second processor.

7. The electronic device of claim 6, wherein the predetermined function comprises an alarm function, and the first state comprises a state in which, while the electronic device is maintained in a user sleep environment, at least one of a motion of the electronic device is detected, a preset voice is input, and an object approaching the electronic device is sensed.

8. The electronic device of claim 7, wherein the first processor comprises a sensor processor, and the second processor comprises an application processor controlling data output, and the predetermined function related information comprises at least one of a time remaining until an alarm time and a current time.

9. The electronic device of claim 8, wherein the one or more computer executable instructions further comprise one or more computer executable instructions for deactivating the activated application processor.

10. The electronic device of claim 8, wherein at least one of the time remaining until the alarm time and the current time is displayed on a touch screen of the electronic device or is outputted by sound through a speaker.

11. A control method of an electronic device, the method comprising:
sensing if the electronic device is in a user sleep environment; and
when the electronic device is in the user sleep environment, at least one of:
if a set volume level is greater than a reference volume level, adjusting the set volume level to the reference volume level; and
if a set screen brightness is greater than a reference screen brightness, adjusting the set screen brightness to the reference screen brightness.

12. The method of claim 11, wherein the sensing if the electronic device is in the user sleep environment comprises sensing through a sensing sensor at least one of a motion of the electronic device, illumination by the electronic device, and whether the electronic device has been laid down with its touch screen facing a surface on which the electronic device has been laid down.

13. The method of claim 12, wherein the sensing if the electronic device is the in the user sleep environment is carried out when a location of the electronic device is a preset location.

14. An electronic device comprising:
one or more processors configured to execute one or more computer executable instructions;
a memory configured to store data and the one or more computer executable instructions,
wherein the one or more computer executable instructions comprise one or more computer executable instructions for sensing if the electronic device is in the a user sleep environment and, when the electronic device is in the user sleep environment, at least one of, if a set volume level is greater than a reference volume level, adjusting the set volume level to the reference volume level and, and if a set screen brightness is greater than a reference screen brightness, adjusting the set screen brightness to the reference screen brightness.

15. The electronic device of claim 14, wherein the sensing if the electronic device is in the user sleep environment comprises sensing through a sensing sensor at least one of a motion of the electronic device, illumination by the electronic device, and whether the electronic device has been laid down with its touch screen facing a surface on which the electronic device has been laid down.

16. The electronic device of claim 15, wherein the sensing if the electronic device is the in the user sleep environment is carried out when a location of the electronic device is a preset location.

17. A control method of an electronic device, the method comprising:
sensing if the electronic device is in a user sleep environment; and
when the electronic device is in the user sleep environment, sensing at least one of a motion of the electronic device and a preset input, and displaying an alarm release pop-up window.

18. The method of claim 17, further comprising, if alarm release is selected in the alarm release pop-up window, releasing a set alarm.

19. The method of claim 17, wherein the sensing if the electronic device is in the user sleep environment comprises sensing through a sensing sensor at least one of a motion of the electronic device, illumination by the electronic device, and whether the electronic device has been laid down with its touch screen facing a surface on which the electronic device has been laid down.

20. The method of claim 19, wherein the sensing if the electronic device is in the user sleep environment is carried out when a location of the electronic device is a preset location.

21. An electronic device comprising:
one or more processors configured to execute one or more computer executable instructions;
a memory configured to store data and the one or more computer executable instructions,
wherein the one or more computer executable instructions comprise one or more computer executable instructions for sensing if the electronic device is in a user sleep environment and, when the electronic device is in the user sleep environment, sensing at least one of a motion of the electronic device and a preset input, and displaying an alarm release pop-up window.

22. The electronic device of claim 21, wherein the instruction further comprises, if alarm release is selected in the alarm release pop-up window, releasing a set alarm.

23. The electronic device of claim 22, wherein the sensing if the electronic device is in the user sleep environment comprises sensing through a sensing sensor at least one of a motion of the electronic device, illumination by the electronic device, and whether the electronic device has been laid down with its touch screen facing a surface on which the electronic device has been laid down.

24. The electronic device of claim 23, wherein the sensing if the electronic device is in the user sleep environment is carried out when a location of the electronic device is a preset location.
